(19) United States
(12) Patent Application Publication
(10) Pub. No.: US 2024/0055414 A1
(43) Pub. Date: Feb. 15, 2024

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventors: Jinwoo Park, Suwon-si (KR); Unbyoung Kang, Suwon-si (KR); Chungsun Lee, Suwon-si (KR)

(21) Appl. No.: 18/299,795

(22) Filed: Apr. 13, 2023

(30) Foreign Application Priority Data
Aug. 10, 2022 (KR) 10-2022-0099793

(51) Int. Cl. H01L 25/10; H01L 23/31; H01L 23/538; H01L 23/498; H01L 23/00; H01L 25/00

(52) U.S. Cl. CPC H01L 25/105; H01L 23/3128; H01L 23/5383; H01L 23/5385; H01L 23/49811; H01L 24/16; H01L 24/32; H01L 24/73; H01L 23/49816; H01L 24/48; H01L 25/50; H01L 2224/16227; H01L 2224/32225; H01L 2224/73253; H01L 2224/48227

(57) ABSTRACT

A semiconductor package includes a first redistribution wiring layer, a first semiconductor device on an upper surface of the first redistribution wiring layer, a first sealing member on the first semiconductor device, a second redistribution wiring layer on the first sealing member such that a peripheral region of a lower surface of the second redistribution wiring layer is free of the first sealing member, at least one second semiconductor device on an upper surface of the second redistribution wiring layer, and a plurality of bonding wirings electrically connecting first redistribution connection pads on a lower surface of the first redistribution wiring layer and second redistribution connection pads on the peripheral region of the lower surface of the second redistribution wiring layer.

### PRIORITY STATEMENT

This application claims priority under 35 U.S.C. § 119 to Korean Patent Application No. 10-2022-0099793, filed on Aug. 10, 2022 in the Korean Intellectual Property Office (KIPO), the contents of which are herein incorporated by reference in their entirety.

### BACKGROUND

### 1. Field

Example embodiments relate to semiconductor packages and methods of manufacturing semiconductor packages. More particularly, example embodiments relate to semiconductor packages including a plurality of stacked different semiconductor chips and methods of manufacturing the same.

### 2. Description of the Related Art

In a Fan Out Wafer Level Package (FOWLP) technology, a conductive structure (Cu Post) is used to connect a lower redistribution wiring layer on which a system semiconductor device is disposed and an upper redistribution wiring layer on which a memory semiconductor device is disposed. As a required height of the conductive structure increases, there fabrication processes may increase in difficulty, a size of a package may increase due to increasing a number of input/output terminals, and/or a manufacturing cost may increase due to a decreasing number of net dies. In addition, it may not be possible to use an exposed Si chip structure that is effective for heat dissipation due to a contamination problem (Cu Contamination) of the conductive structure.

### SUMMARY

Example embodiments provide a semiconductor package including a plurality of bonding wirings to reduce manufacturing cost and implement a structure for effective heat emission.

Example embodiments provide a method of manufacturing the semiconductor package.

According to example embodiments, a semiconductor package includes a first redistribution wiring layer, a first semiconductor device on an upper surface of the first redistribution wiring layer, a first sealing member on the first semiconductor device, a second redistribution wiring layer on the first sealing member, such that a peripheral region of a lower surface of the second redistribution wiring layer is free of the first sealing member, at least one second semiconductor device on an upper surface of the second redistribution wiring layer, and a plurality of bonding wirings electrically connecting first redistribution connection pads on a lower surface of the first redistribution wiring layer and second redistribution connection pads on the peripheral region of the lower surface of the second redistribution wiring layer.

According to example embodiments, in a method of manufacturing a semiconductor package, a first sub-package including a first semiconductor device on a first redistribution wiring layer and a first sealing member on the first semiconductor device is formed. The first redistribution wiring layer has first redistribution connection pads on a lower surface of the first redistribution wiring layer. A second sub-package including a second semiconductor device on a second redistribution wiring layer and a second sealing member on the second redistribution wiring layer is formed. The second redistribution wiring layer having second redistribution connection pads on a lower surface of a peripheral region of the second redistribution wiring layer. The first sealing member is bonded to the second redistribution wiring layer to stack the second sub-package on the first sub-package. A plurality of bonding wirings electrically connecting the first and second redistribution connection pads to each other is formed.

According to example embodiments, a semiconductor package includes a first sub-package having a first upper surface and a first lower surface opposite to each other, the first sub-package having a first redistribution wiring layer having a plurality of first redistribution connection pads exposed from the first lower surface, a first semiconductor device on the first redistribution wiring layer and a first sealing member on the first semiconductor device, a second sub-package having a second upper surface and a second lower surface opposite to each other, the second sub-package having a second redistribution wiring layer having a plurality of second redistribution connection pads and external connection redistribution pads exposed from the second lower surface, a second semiconductor device mounted on the second redistribution wiring layer, and a second sealing member on the second semiconductor device, an adhesive member between the first upper surface of the first sub-package and the second lower surface of the second sub-package to bond the first and second sub-packages, a plurality of first bonding wirings electrically connecting the first and second redistribution connection pads to each other, and external connection bumps on the external connection redistribution pads, respectively.

According to example embodiments, a semiconductor package may include a first redistribution wiring layer, a first semiconductor device on an upper surface of the first redistribution wiring layer, a first sealing member on the first semiconductor device, a second redistribution wiring layer on the first sealing member and configured to expose a peripheral region of a lower surface thereof from the first sealing member, at least one second semiconductor device on an upper surface of the second redistribution wiring layer, and a plurality of bonding wirings electrically connecting first redistribution connection pads on a lower surface of the first redistribution wiring layer and second redistribution connection pads on the peripheral region of the lower surface of the second redistribution wiring layer.

Thus, the first and second redistribution wiring layers may be electrically connected through the bonding wirings to provide high-density interconnection between a first sub-package and a second sub-package. Because the bonding wirings having less space restrictions are used without using a conductive structure (Cu post), which may be used in a Fan Out Wafer Level Package (FOWLP) technology, it may be possible to form a thin profile package structure. In addition, a semiconductor manufacturing process may be simplified, and a high yield may be obtained by using the bonding wiring instead of the conductive structure. Because the bonding wiring has little space restriction, the number of input/output terminals and the number of net dies may be increased. Because it is relatively easy to change to a structure that reduces solder ball joints, effective heat emission characteristics may be obtained. Because the first sub-package and the second sub-package form a symmetrical structure to each other, a warpage phenomenon may be controlled.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 is a cross-sectional view illustrating a semiconductor package in accordance with example embodiments.

FIGS. 2 to 13 are cross-sectional views illustrating a method of manufacturing a semiconductor package in accordance with example embodiments.

FIG. 14 is a cross-sectional view illustrating a semiconductor package including a semiconductor device mounted on an upper redistribution wiring layer by solder bumps in accordance with example embodiments.

FIGS. 15 to 17 are cross-sectional views illustrating a method of manufacturing a semiconductor package in FIG. 14 in accordance with example embodiments.

### DETAILED DESCRIPTION OF EXAMPLE EMBODIMENTS

Hereinafter, example embodiments will be explained in detail with reference to the accompanying drawings. The present disclosure may, however, be embodied in many different forms and should not be construed as limited to the embodiments set forth herein. Like reference numerals refer to like elements throughout this application. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

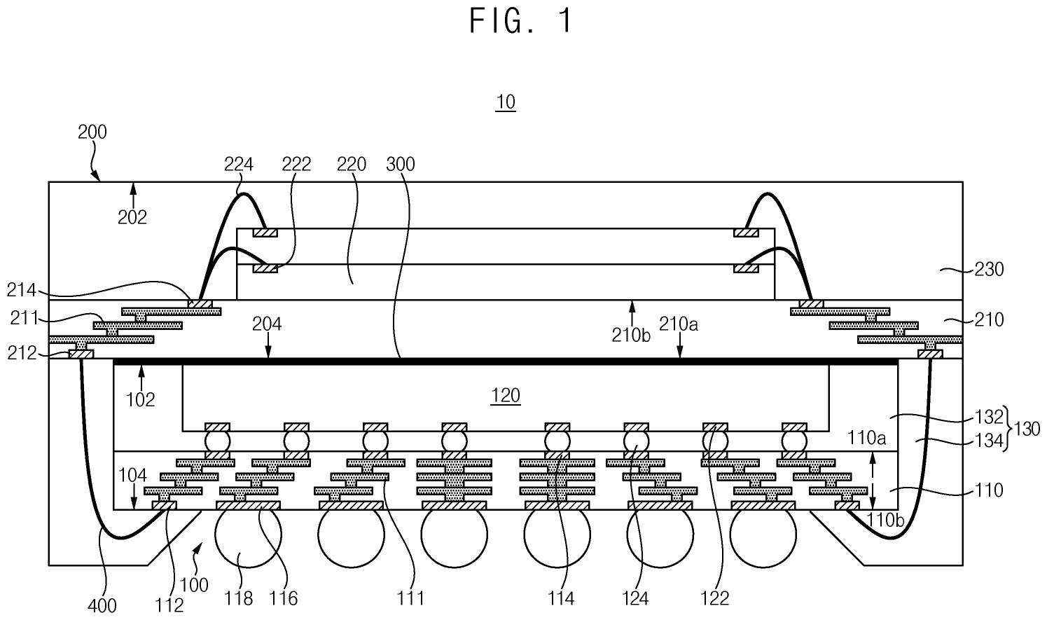

FIG. 1 is a cross-sectional view illustrating a semiconductor package in accordance with example embodiments.

Referring to FIG. 1, a semiconductor package 10 may include a first sub-package 100 having a first redistribution wiring layer 110 and a first semiconductor device 120, a second sub-package 200 having a second redistribution wiring layer 210 and a second semiconductor device 220, an adhesive member 300 for bonding the first and second sub-packages 100, 200, and a plurality of first bonding wirings 400 configured to electrically connect the first and second redistribution wiring layers 110, 210.

In example embodiments, the first sub-package 100 may include a first upper surface 102 and a first lower surface 104 opposite to each other. The first sub-package 100 may include a first redistribution wiring layer (lower redistribution wiring layer) 110, a first semiconductor device 120 disposed on the first redistribution wiring layer 110, and a first sealing member 130 on and at least partially covering the first semiconductor device 120. The first sub-package 100 may further include external connection bumps 118 that are configured to be electrically connected to other semiconductor devices.

In example embodiments, the first redistribution wiring layer 110 may be provided on the first lower surface 104 of the first sub-package 100. The first redistribution wiring layer 110 may include first and second surfaces 110a, 110b opposite to each other. The first redistribution wiring layer 110 may be configured to expose the second surface 110b to the first lower surface 104 of the first sub-package 100. For example, a first thickness of the first redistribution wiring layer 110 may be within a range of 40 μm to 100 μm. The first redistribution wiring layer 110 may include a photosensitive resin (photopolymer).

The first redistribution wiring layer 110 may include a plurality of first redistribution wirings 111 and first insulating layers. The first redistribution wiring layer 110 may include a plurality of first connection pads 114 configured to be exposed on the upper surface of the first redistribution wiring layer 110, that is, the first surface 110a, and a plurality of first redistribution connection pads 112 and a plurality of external connection redistribution pads 116 are configured to be exposed on the lower surface of the first redistribution wiring layer 110, that is, the second surface 110b.

The first redistribution wirings 111 may be provided in the first insulating layers. The first redistribution wirings 111 may electrically connect the first connection pads 114, the first redistribution connection pads 112, and the external connection redistribution pads 116 to each other. The first redistribution wiring 111 may electrically connect the first and second semiconductor devices 120, 220. For example, the first redistribution wiring 111 may include aluminum (Al), copper (Cu), tin (Sn), nickel (Ni), gold (Au), platinum (Pt), or an alloy thereof. The first redistribution wiring 111 may be formed by a plating process, an electroless plating process, a vapor deposition process, or the like.

The first insulating layers may include first openings that expose the first redistribution connection pads 112 to the second surface 110b, second openings that expose the first connection pads 114 to the first surface 110a, and third openings that expose the external connection redistribution pads 116 to the second surface 110b. For example, the first insulating layers may include a polymer, a dielectric layer, or the like. The first insulating layers may be formed by a vapor deposition process, a spin coating process, or the like.

The first redistribution connection pad 112 may be provided in the first insulating layer. The first redistribution connection pad 112 may contact to the first redistribution wiring 111 through the first opening. Accordingly, the plurality of first redistribution connection pads 112 may be configured to be exposed from the lower surface of the first redistribution wiring layer 110, that is, the second surface 110b. The first redistribution connection pad 112 may be electrically connected to the first bonding wire 400 to electrically connect the first and second semiconductor devices 120, 220.

The first connection pad 114 may be provided in the first insulating layer. The first connection pad 114 may contact the first redistribution wiring 111 through the second opening. Accordingly, the plurality of first connection pads 114 may be configured to be exposed from the upper surface of the first redistribution wiring layer 110, that is, the first surface 110a. The first connection pads 114 may respectively contact first solder bumps 124 of the first semiconductor device 120.

The external connection redistribution pad 116 may be provided in the first insulating layer. The external connection redistribution pad 116 may contact the first redistribution wiring 111 through the third opening. Accordingly, the plurality of external connection redistribution pads 116 may be configured to be exposed from the lower surface of the first redistribution wiring layer 110, that is, the second surface 110b. The external connection bumps 118 may be respectively provided on the external connection redistribution pads 116.

The first redistribution wiring layer 110 may be connected to other semiconductor devices through the external connection bumps 118 as conductive connection members. The external connection bumps 118 may be respectively provided on the external connection redistribution pads 116. For example, the external connection bump 118 may include a C4 bump. The external connection redistribution pad 116 of the first redistribution wiring layer 110 may be electrically connected to a substrate pad of the package substrate by the external connection bumps 118.

The first redistribution connection pad 112, the first connection pad 114, the external connection redistribution pad 116, and the first redistribution wiring 111 may include the same conductive metal material. For example, the conductive metal material may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), or an alloy thereof.

In example embodiments, the first semiconductor device 120 may include first chip pads 122 provided on a lower surface and first solder bumps 124 respectively provided on the first chip pads 122. The first semiconductor device 120 may be disposed on the first surface 110a of the first redistribution wiring layer 110.

The first semiconductor device 120 may be disposed on the first redistribution wiring layer 110 by a flip chip bonding method. In this case, the first semiconductor device 120 may be disposed on the first redistribution wiring layer 110, such that an active surface on which the first chip pads 122 are formed faces the first redistribution wiring layer 110. The first chip pads 122 of the first semiconductor device 120 may be electrically connected to the first connection pads 114 of the first redistribution wiring layer 110 by first solder bumps 124 as conductive connection members. For example, the first solder bumps 124 may include micro bumps (uBump).

In example embodiments, the first sealing member 130 may be on and at least partially cover the first redistribution wiring layer 110, the first semiconductor device 120, and the first bonding wiring 400. The first sealing member 130 may be provided on the first redistribution wiring layer 110 to at least partially fill a space between the first and second redistribution wiring layers 110, 210.

The first sealing member 130 may include a sealing layer 132 and a sealing structure 134. The sealing layer 132 may be provided on the first surface 110a of the first redistribution wiring layer 110 to border or surround the first semiconductor device 120. The sealing structure 134 may extend from the sealing layer 132. The sealing structure 134 may border or surround the first bonding wirings 400 configured to be provided on at least a portion of an outer surface and the second surface 110b of the first redistribution wiring layer 110, the first redistribution connection pad 112, and the sealing layer 132. The sealing structure 134 may expose the external connection redistribution pads 116 provided on the second surface 110b of the first redistribution wiring layer 110.

The first sealing member 130 may include a plurality of first through lines through which the first bonding wiring 400 is inserted. In the first through line, one end of the first bonding wiring 400 may be connected to the first redistribution connection pad 112 of the first redistribution wiring layer 110, and the other end of the first bonding wiring 400 may be connected to the second redistribution connection pad 212 of the second redistribution wiring layer 210.

The second sub-package 200 may be disposed on the first sealing member 130. The first sealing member 130 may have a parallel upper area, such that the second redistribution wiring layer 210 of the second sub-package 200 may be disposed thereon. For example, the first sealing member 130 may include an epoxy mold compound (EMC).

In example embodiments, the second sub-package 200 may include a second upper surface 202 and a second lower surface 204 opposite to each other. The second sub-package 200 may include the second redistribution wiring layer (upper redistribution wiring layer) 210, the second semiconductor device 220 disposed on the second redistribution wiring layer 210, and a second sealing member 230 on and at least partially covering the second semiconductor device 220.

In example embodiments, the second redistribution wiring layer 210 may be provided on the second lower surface 204 of the second sub-package 200. The second redistribution wiring layer 210 may include third and fourth surfaces 210a, 210b opposite to each other. The second redistribution wiring layer 210 may be configured to expose the fourth surface 210b to the second lower surface 204 of the second sub-package 200. For example, a second thickness of the second redistribution wiring layer 210 may be within a range of 40 μm to 100 μm. The second redistribution wiring layer 210 may include a photosensitive resin (photopolymer). The second redistribution wiring layer 210 may be replaced with a printed circuit board (PCB).

The second redistribution wiring layer 210 may include a plurality of second redistribution wirings 211 and second insulating layers. The second redistribution wiring layer 210 may include a plurality of second connection pads 214 configured to be exposed to the upper surface of the second redistribution wiring layer 210, that is, the third surface 210a, and a plurality of second redistribution connection pads 212 are configured to be exposed to the lower surface of the second redistribution wiring layer 210, that is, the fourth surface 210b.

The second redistribution wirings 211 may be provided in the second insulating layers. The second redistribution wirings 211 may electrically connect the second connection pads 214 and the first redistribution connection pads 112 to each other. The second redistribution wiring 211 may electrically connect the first and second semiconductor devices 120, 220. For example, the second redistribution wiring 211 may include aluminum (Al), copper (Cu), tin (Sn), nickel (Ni), gold (Au), platinum (Pt), or an alloy thereof. The second redistribution wiring 211 may be formed by a plating process, an electroless plating process, a vapor deposition process, or the like.

The second insulating layers may include fourth openings that expose the second redistribution connection pads 212 to the fourth surface 210b, and fifth openings that expose the second connection pads 214 to the third surface 210a. For example, the second insulating layer may include a polymer, a dielectric layer, or the like. The second insulating layer may be formed by a vapor deposition process, a spin coating process, or the like.

The second redistribution connection pad 212 may be provided in the second insulating layer. The second redistribution connection pad 212 may contact the second redistribution wiring 211 through the fourth opening. Accordingly, the plurality of second redistribution connection pads 212 may be configured to be exposed from the lower surface of the second redistribution wiring layer 210, that is, the fourth surface 210b. The second redistribution connection pad 212 may be electrically connected to the first bonding wiring 400 to electrically connect the first and second semiconductor devices 120, 220.

The second connection pad 214 may be provided in the second insulating layer. The second connection pad 214 may contact the second redistribution wiring 211 through the fifth opening. Accordingly, the plurality of second connection pads 214 may be configured to be exposed from the upper surface of the second redistribution wiring layer 210, that is, the third surface 210a. The second connection pads 214 may respectively contact the second bonding wiring 224 of the second semiconductor device 220.

The second redistribution connection pad 212, the second connection pad 214, and the second redistribution wiring 211 may include the same conductive metal material. For example, the conductive metal material may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), or an alloy thereof.

In example embodiments, the second semiconductor device 220 may include second chip pads 222 provided on an upper surface, and second bonding wiring 224 respectively extending from the second chip pads 222. The second semiconductor device 220 may be disposed on the third surface 210a of the second redistribution wiring layer 210.

The second semiconductor device 220 may be disposed on the second redistribution wiring layer 210 by a wire bonding method. In this case, the second semiconductor device 220 may be disposed on the second redistribution wiring layer 210, such that the active surface on which the second chip pads 222 are formed faces the opposite direction of the second redistribution wiring layer 210. The second chip pads 222 of the second semiconductor device 220 may be electrically connected to the second connection pads 214 of the second redistribution wiring layer 210 by the second bonding wirings 224 as conductive connection members.

In example embodiments, the second sealing member 230 may be on and at least partially cover the second redistribution wiring layer 210 and the second semiconductor device 220. The second sealing member 230 may include a plurality of second through lines through which the second bonding wiring 224 is inserted. One end of the second bonding wiring 224 in the second through line may be connected to the second connection pad 214 of the second redistribution wiring layer 210, and the other end of the second bonding wiring 224 may be connected to the second chip pad 222 of the second semiconductor device 220. For example, the second sealing member 230 may include an epoxy mold compound (EMC).

In example embodiments, the first bonding wiring 400 may pass through the first sealing member 130 to electrically connect the first redistribution wiring layer 110 and the second redistribution wiring layer 210. The first bonding wiring 400 may be provided outside the first sub-package 100. The first bonding wiring 400 may be provided in the first through lines of the sealing structure 134. The first bonding wiring 400 may extend from the first redistribution connection pad 112 of the first sub-package 100 to the second redistribution connection pad 212 of the second sub-package 200. The first bonding wirings 400 may provide high-density interconnection between the first and second redistribution wiring layers 110, 210.

Specifically, the first bonding wiring 400 may be electrically connected to the first redistribution connection pad 112 of the first redistribution wiring layer 110. The first bonding wiring 400 may be electrically connected to the second redistribution connection pad 212 of the second redistribution wiring layer 210. The first bonding wiring 400 may provide a signal transmission path for electrically connecting the first and second redistribution wiring layers 110, 210.

For example, the first bonding wire 400 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), and/or tin (Sn).

Although one first semiconductor device 120 and one second semiconductor device 220 are illustrated in the figures, embodiments may not be limited thereto. For example, the second semiconductor device 220 may include a buffer die and a plurality of memory dies (chips) sequentially stacked on the buffer die.

Although only some substrates, some bonding pads, and some wirings are illustrated in the drawings, it may be understood that the number and arrangement of the substrates, the bonding pads, and the wirings are examples, and embodiments may be not limited thereto. In the interest of brevity and conciseness, illustration and description concerning some of the wirings and the substrates will be omitted.

As described above, the first bonding wirings 400 may electrically connect the first and second redistribution wiring layers 110, 210 to provide the high-density interconnection between the first sub-package 100 and the second sub-package 200. Because the first bonding wirings 400 having less space restrictions are used without using the conductive structure (Cu post) used in the Fan Out Wafer Level Package (FOWLP) technology, a thin profile package structure may be formed.

In addition, a semiconductor manufacturing process may be simplified, and a high yield may be obtained by using the first bonding wiring 400 instead of the conductive structure. Because the first bonding wiring 400 has little space restriction, the number of input/output terminals and the number of net dies may be increased. Because it is relatively easy to change to a structure that reduces solder ball joints, effective heat emission characteristics may be obtained. Because the first sub-package 100 and the second sub-package 200 form a symmetrical structure to each other, a warpage phenomenon may be controlled.

Hereinafter, a method of manufacturing the semiconductor package in FIG. 1 will be described.

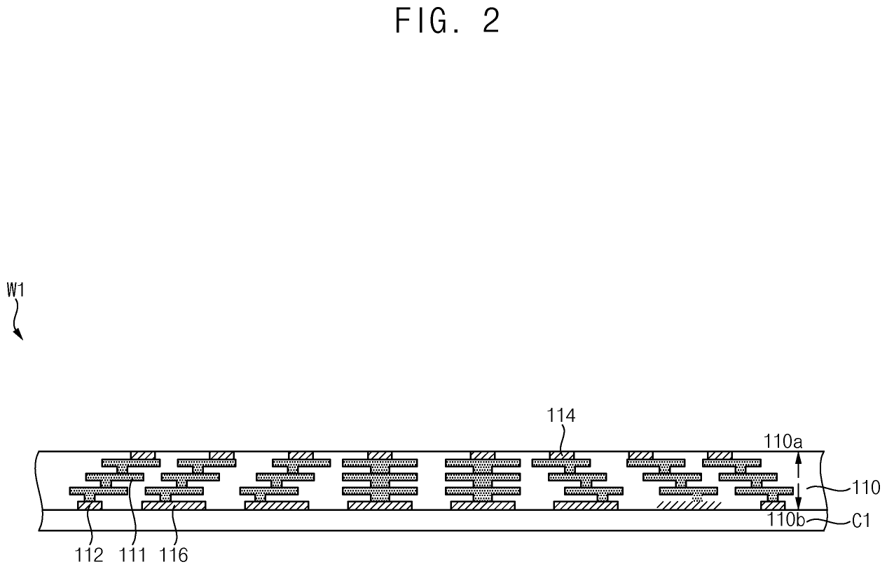

FIGS. 2 to 13 are cross-sectional views illustrating a method of manufacturing a semiconductor package in accordance with example embodiments.

First, a method of manufacturing a first sub-package 100 will be described.

Referring to FIG. 2, a first semiconductor wafer W1 including a first redistribution wiring layer 110 having a plurality of first redistribution connection pads 112, a plurality of first connection pads 114 and a plurality of external connection redistribution pads 116 may be formed. The first semiconductor wafer W1 may be a base wafer on which a plurality of first sub-packages 100 is formed.

A first photoresist film may be formed on a first carrier substrate C1 of the base wafer, and an exposure process may be performing on the first photoresist film to form a first photoresist pattern having first temporary openings that exposes regions for forming the first redistribution connection pad 112 and external connected redistribution pads 116. Then, a plating process may be performed to form a first metal pattern and the first photoresist pattern may be removed from the first carrier substrate C1 to form the first redistribution connection pads 112 and the external connection redistribution pads 116. The first redistribution connection pads 112 may be formed in an outer region of the first redistribution wiring layer 110 bordering or surrounding the external connection redistribution pads 116.

Then, after a first insulating layer is formed to be on and at least partially cover the first redistribution connection pad 112 and the external connection redistribution pads 116, the first insulating layer may be patterned to form first and third openings that expose the first redistribution connection pad 112 and the external connection redistribution pad 116.

For example, the first insulating layer may include a polymer, a dielectric layer, or the like. The first insulating layer may include polyimide (PI), lead oxide (PbO), polyhydroxystyrene (PHS), NOVOLAC, or the like. The first insulating layer may be formed by a vapor deposition process, a spin coating process, or the like.

First redistribution wirings 111 may be formed on the first and third openings. The first redistribution wirings 111 may directly contact the first redistribution connection pad 112 and the external connection redistribution pads 116 through the first and third openings. For example, the first redistribution wirings may include aluminum (Al), copper (Cu), tin (Sn), nickel (Ni), gold (Au), platinum (Pt), or an alloy thereof. The first redistribution wirings 111 may be formed by an electrolytic plating process or an electroless plating process.

Then, additional first insulating layers may be formed on the first insulating layer and the first redistribution wirings 111 may be formed in the first redistribution wiring layer 110 including the first insulation layer and the additional first insulating layers, and then, the first connection pads 114 may be formed by a plating process. The first redistribution wiring layer 110 may have a first surface 110a to which the first connection pads 114 are exposed and a second surface 110b opposite to the first surface 110a.

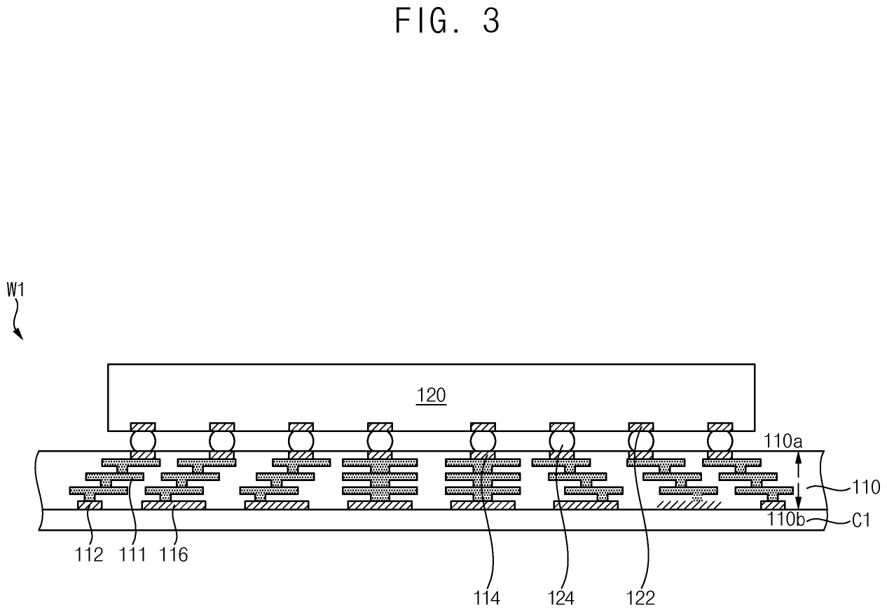

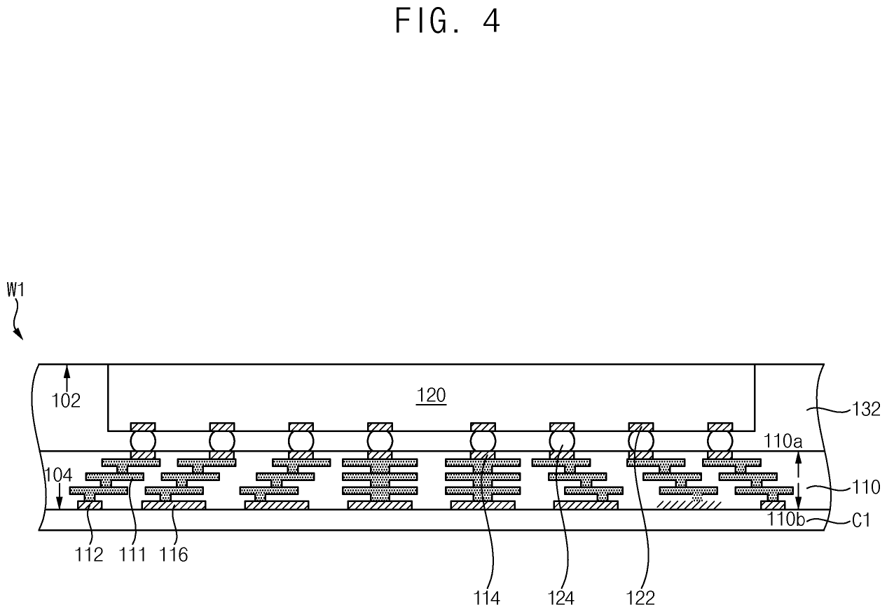

Referring to FIGS. 3 and 4, after a first semiconductor device is disposed on the first redistribution wiring layer 110, a sealing layer 132 may be formed on the first redistribution wiring layer 110 to be on and at least partially cover the first semiconductor device 120.

In example embodiments, the first semiconductor device 120 may be mounted on the first redistribution wiring layer 110 by a flip chip bonding method. First chip pads 122 of the first semiconductor device 120 may be electrically connected to the first connection pads 114 of the first redistribution wiring layer 110 by first solder bumps 124. For example, the first solder bumps 124 may include micro bumps (uBump).

The first semiconductor device 120 may be attached on the first surface 110a of the first redistribution wiring layer 110 by performing a thermal compression process at a predetermined temperature (e.g., about 400° C. or less). The first semiconductor device 120 and the first redistribution wiring layer 110 may be bonded to each other via the first solder bumps through the thermal compression process. That is, the first solder bumps 124 of the first semiconductor device 120 may be respectively bonded to the first connection pads 114 formed on the first surface 110a of the first redistribution wiring layer 110.

For example, the sealing layer 132 may include an epoxy mold compound (EMC). The sealing layer 132 may be formed to expose an upper surface of the first semiconductor device 120.

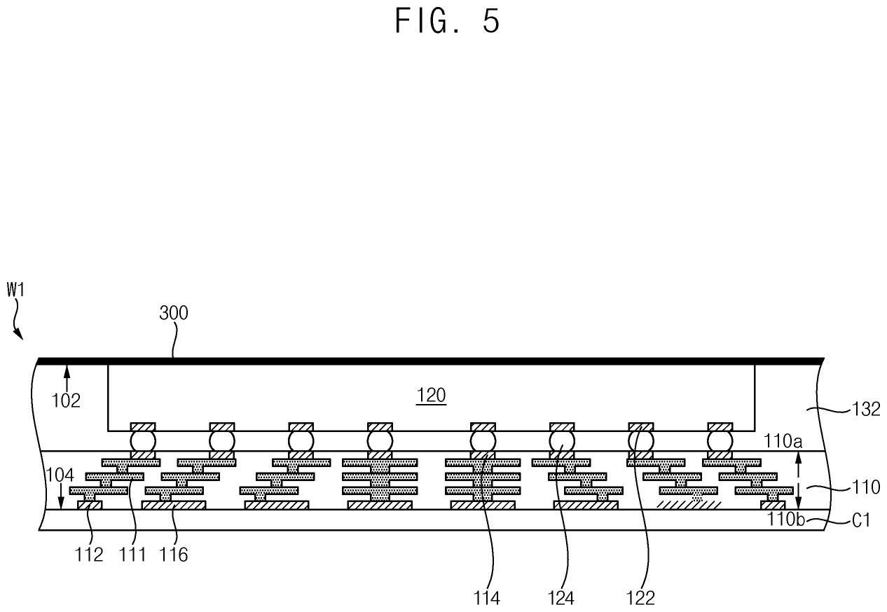

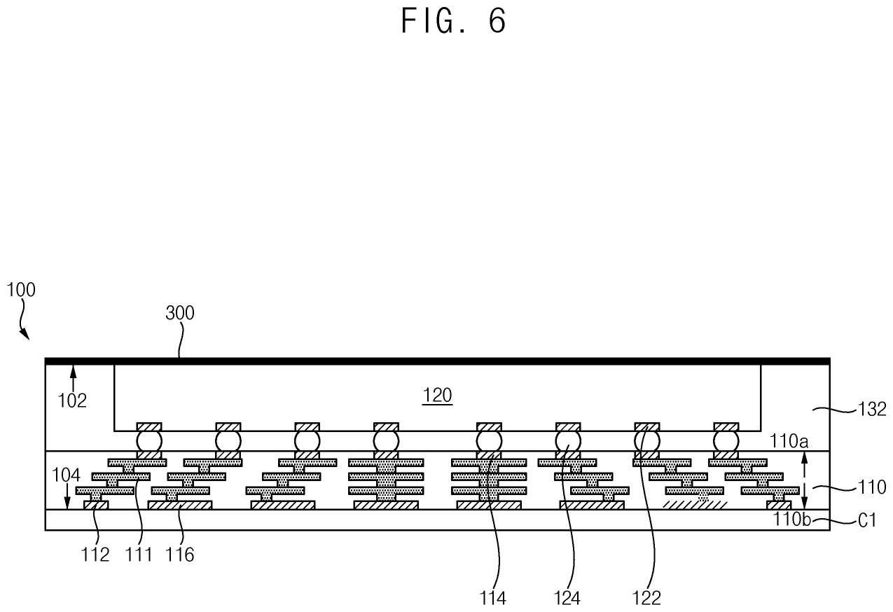

Referring to FIGS. 5 and 6, after forming an adhesive member 300 on the sealing layer 132, the first semiconductor wafer W1 may be cut to form the first sub-package 100. The first sub-package 100 may have a first upper surface 102 on which the adhesive member 300 is formed and a first lower surface 104 opposite to the first upper surface.

An upper surface of the sealing layer 132 may be partially removed by a grinding process, such as a chemical mechanical polishing (CMP) process. The upper surface of the sealing layer 132 may be polished to have a generally even surface. Accordingly, a thickness of the sealing layer 132 may be reduced to a desired thickness. The upper surface of the first semiconductor device 120 may be exposed from the upper surface of the sealing layer 132.

The adhesive member 300 may be formed on the upper surface of the sealing layer 132. The adhesive member 300 may include an adhesive material having adhesive strength on both surfaces thereof. The first sub-package 100 may be attached to one surface of the adhesive member 300 and a second sub-package 200 may be attached to the other surface of the adhesive member 300. For example, the adhesive member 300 may include an epoxy compound, a phenol resin compound, or the like. The adhesive member 300 may be formed by a vapor deposition process, a spin coating process, a sputtering process, etc. to be generally uniformly coated on the upper surface of the sealing layer 132.

The first semiconductor wafer W1 may be cut through a sawing process. The plurality of first sub-packages 100 may be obtained by cutting the first semiconductor wafer W1. For example, the first semiconductor wafer W1 may be cut along a scribe lane in the sawing process.

Next, a method of manufacturing the second sub-package 200 will be described.

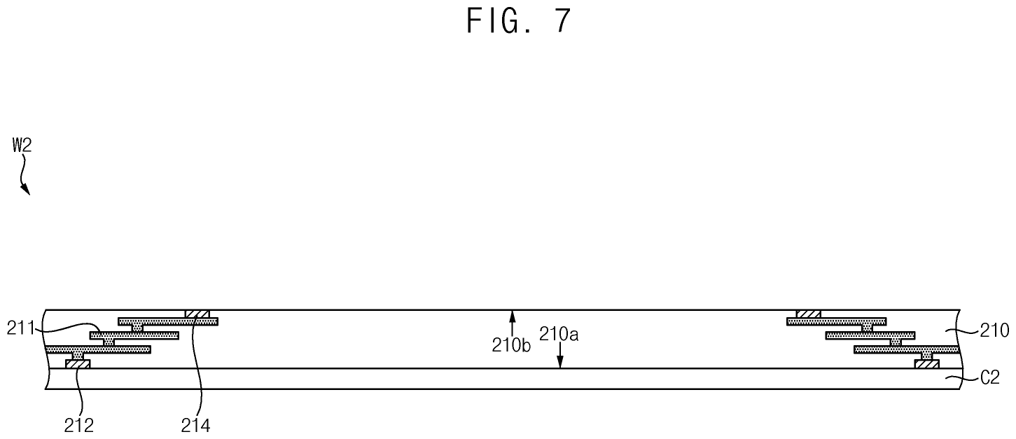

Referring to FIG. 7, a second semiconductor wafer W2 including a second redistribution wiring layer 210 having a plurality of second redistribution connection pads 212 and a plurality of second connection pads 214 may be formed. The second semiconductor wafer W2 may be a base wafer on which a plurality of second sub-packages 200 is formed.

A second photoresist film may be formed on a second carrier substrate C2 of the base wafer, and an exposure process is performed on the second photoresist film to form a second photoresist pattern having second temporary openings that expose regions for forming the second redistribution connection pad 212. Then, a plating process may be performed to form a second metal pattern, and the second photoresist pattern may be removed to form the second redistribution connection pads 212. The second redistribution connection pads 212 may be formed in an outer region of the second redistribution wiring layer 210.

Then, after a second insulating layer is formed to be on and at least partially cover the second redistribution connection pads 212, the second insulating layer may be patterned to form fourth openings that expose the second redistribution connection pads 212.

For example, the second insulating layer may include a polymer, a dielectric layer, or the like. The second insulating layer may include polyimide (PI), lead oxide (PbO), polyhydroxystyrene (PHS), NOVOLAC, or the like. The second insulating layer may be formed by a vapor deposition process, a spin coating process, or the like.

Second redistribution wirings 211 may be formed on the fourth openings. The second redistribution wirings 211 may directly contact the second redistribution connection pads 212 through fourth openings. For example, the second redistribution wirings 211 may include aluminum (Al), copper (Cu), tin (Sn), nickel (Ni), gold (Au), platinum (Pt), or an alloy thereof. The second redistribution wirings 211 may be formed by an electrolytic plating process or an electroless plating process.

Then, additional second insulating layers may be formed on the second insulating layer and the second redistribution wirings 211 may be formed in the second redistribution wiring layer 210 including the second insulating layer and the additional second insulating layers, and then, the second connection pads 214 may be formed by performing a plating process. The second redistribution wiring layer 210 may have a third surface 210a to which the second connection pads 214 are exposed and a fourth surface 210b opposite to the third surface 210a.

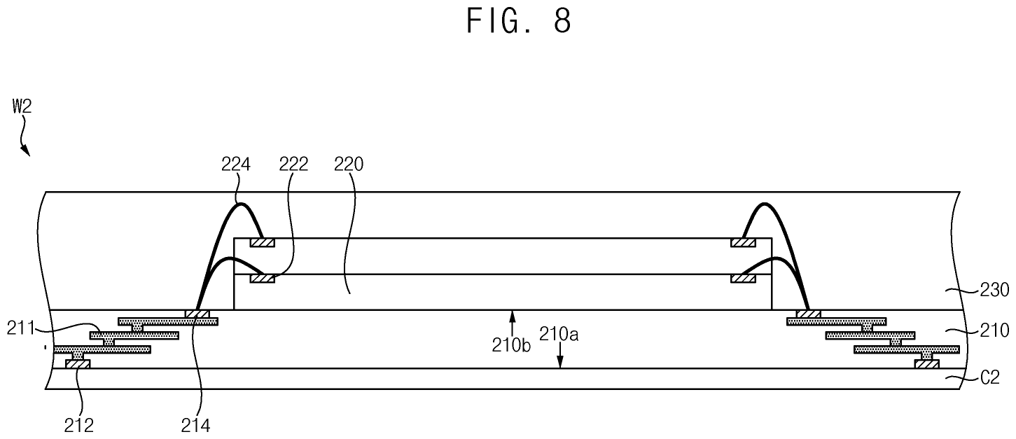

Referring to FIG. 8, after the second semiconductor device is disposed on the second redistribution wiring layer 210, a second sealing member 230 on and at least partially covering the second semiconductor device 220 may be formed on the second redistribution wiring layer 210.

In example embodiments, the second semiconductor device 220 may be mounted on the second redistribution wiring layer 210 by a wire bonding method. Second chip pads 222 of the second semiconductor device 220 may be electrically connected to the second connection pads 214 of the second redistribution wiring layer 210 by second bonding wirings 224.

For example, the second sealing member 230 may include an epoxy mold compound (EMC).

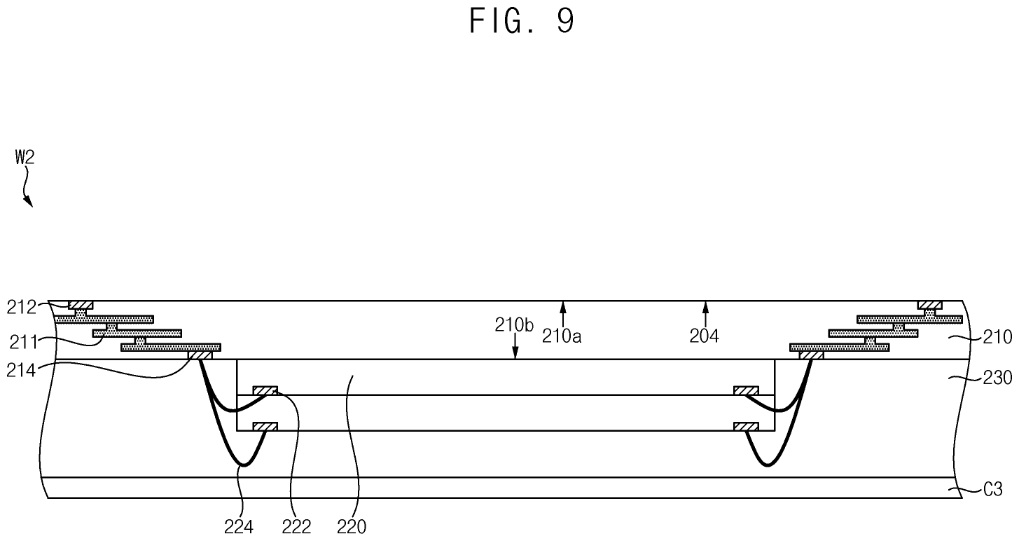

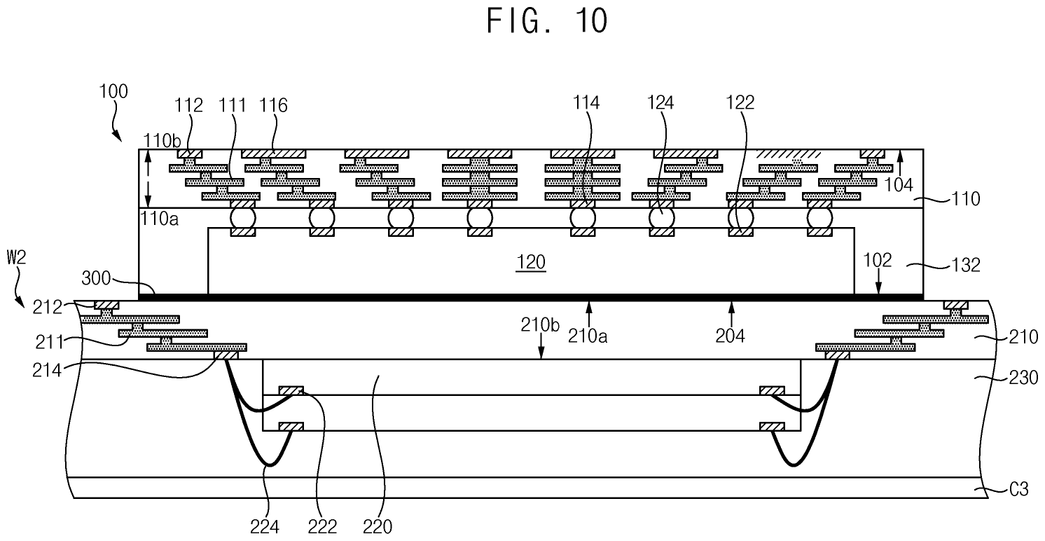

Referring to FIGS. 9 and 10, after a third carrier substrate C3 is attached on the second sealing member 230, the structure to which the third carrier substrate C3 is attached may be turned over, and the second carrier substrate C2 on the third surface 210a of the second redistribution wiring layer 210 may be removed. Accordingly, the second redistribution connection pads 212 may be exposed from the third surface 210a of the second redistribution wiring layer 210.

The first sub-package 100 may be adhered to the second redistribution wiring layer 210 of the second semiconductor wafer W2 through the adhesive member 300. The first sub-package 100 may be adhered to a position corresponding to the second sub-package 200 of the second semiconductor wafer W2.

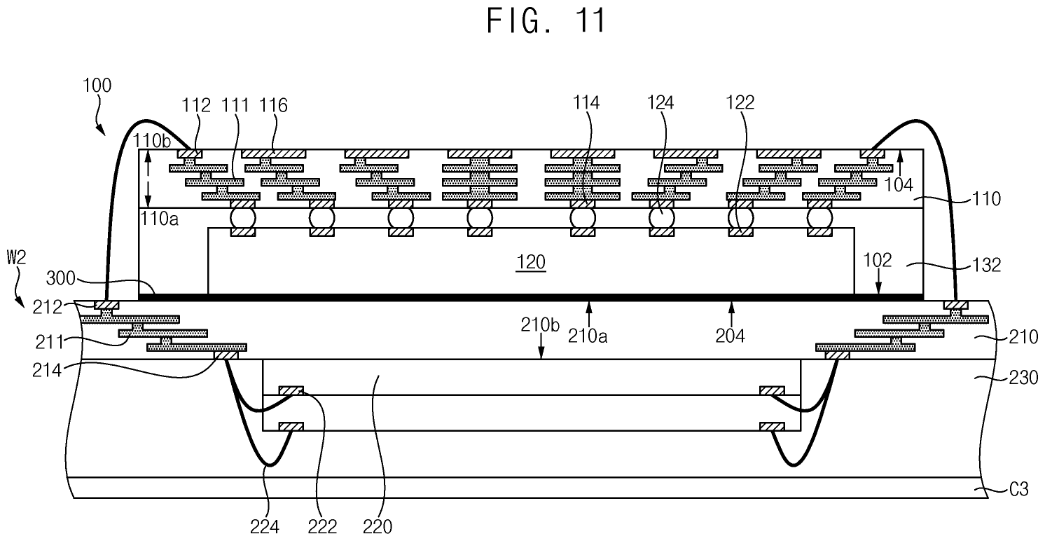

Referring to FIG. 11, first bonding wirings 400 may be formed to connect the second semiconductor wafer W2 and the first sub-package 100.

The first bonding wiring 400 may be provided outside the first sub-package 100. The first bonding wiring 400 may extend from the first redistribution connection pad 112 of the first sub-package 100 to the second redistribution connection pad 212 of the second semiconductor wafer W2.

In particular, one end of the first bonding wiring 400 may be electrically connected to the first redistribution connection pad 112 of the first redistribution wiring layer 110. The other end of the first bonding wiring 400 may be electrically connected to the second redistribution connection pad 212 of the second redistribution wiring layer 210. The first bonding wiring 400 may provide a signal transmission path for electrically connecting the first and second redistribution wiring layers 110, 210.

For example, the first bonding wire 400 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), and/or tin (Sn).

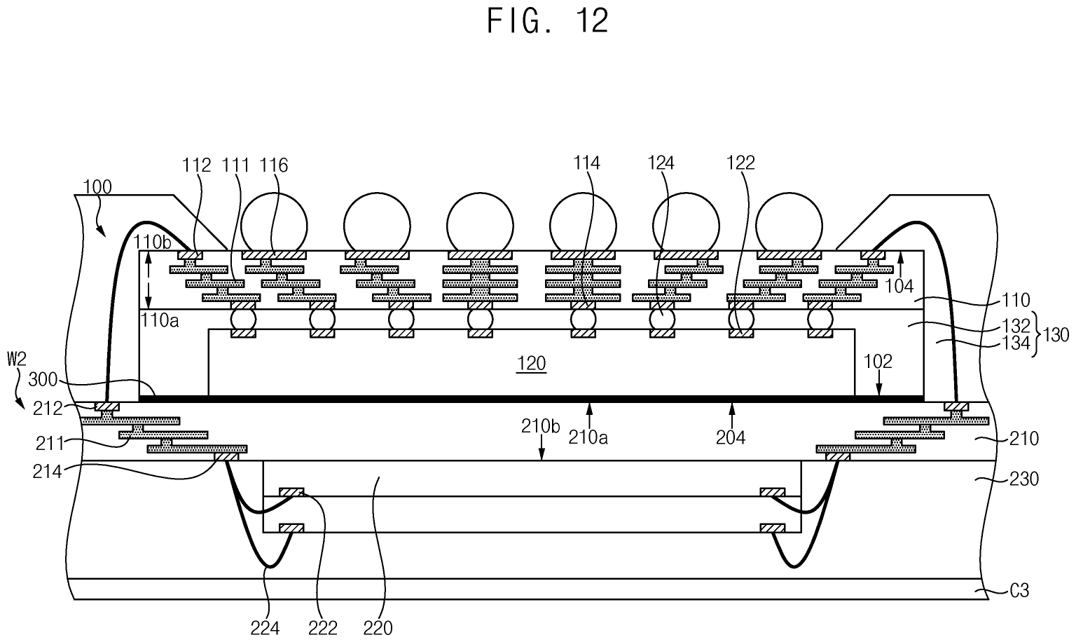

Referring to FIG. 12, a sealing structure 134 may be formed to be on and cover at least a portion of the first sub-package 100, the first bonding wiring 400, and the third surface 210a of the second redistribution wiring layer 210.

The sealing structure 134 may be formed on the first surface 110a of the first redistribution wiring layer 110 to border or surround the first sub-package 100. The sealing structure 134 may be formed to extend from the sealing layer 132. The sealing structure 134 may be formed on at least a portion of the outer surface and the second surface 110b of the first redistribution wiring layer 110, and the sealing structure 134 may be on and cover at least a portion of the first bonding wirings 400, the first redistribution connection pad 112, and the sealing layer 132. The sealing structure 134 may expose the external connection redistribution pads 116 provided on the second surface 110b of the first redistribution wiring layer 110.

The first bonding wiring 400 may be provided as a first through line in the sealing structure 134, one end of the first bonding wiring 400 may be connected to the first redistribution connection pad 112 of the first redistribution wiring layer 110, and the other end of the first bonding wiring 400 may be connected to the second redistribution connection pad 212 of the second redistribution wiring layer 210.

External connection bumps 118 may be respectively formed on the external connection redistribution pads 116. In particular, after a third temporary opening of a third photoresist pattern is at least partially filled with a conductive material, the external connection bumps 118 may be formed by removing the third photoresist pattern and performing a reflow process. For example, the conductive material may be formed by a plating process. In other embodiments, the external connection bumps 118 may be formed by a screen printing method, a vapor deposition method, or the like. For example, the external connection bumps 118 may include a C4 bump.

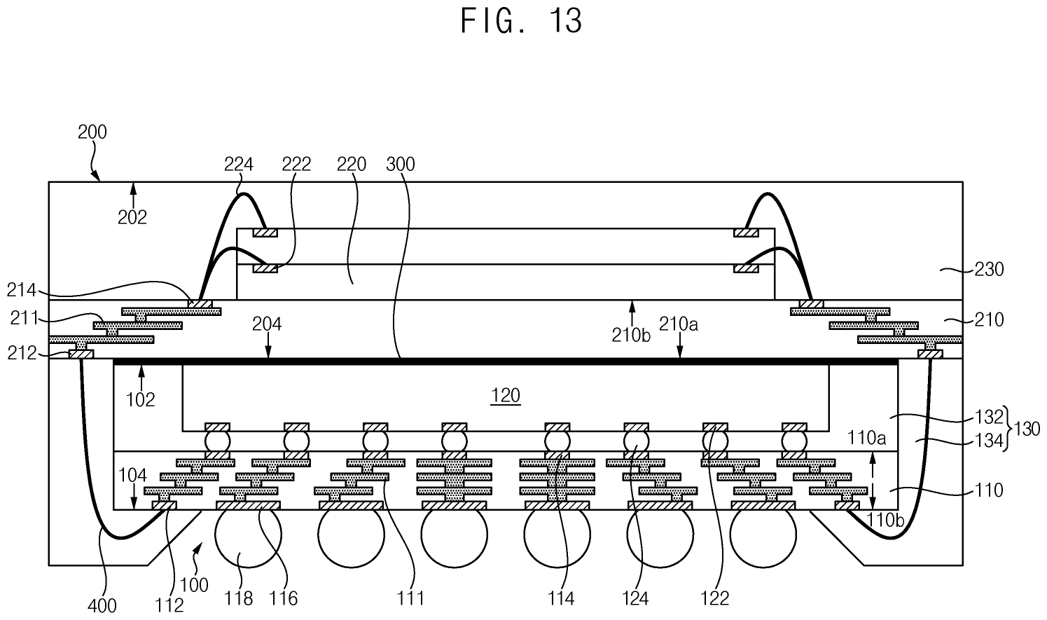

Referring to FIG. 13, the individual semiconductor package 10 may be formed by cutting the second semiconductor wafer W2 along a scribe lane. The second semiconductor wafer W2 may be cut by a dicing process. The semiconductor package 10 including the first sub-package 100 and the second sub-package 200 may be formed by cutting the second semiconductor wafer W2.

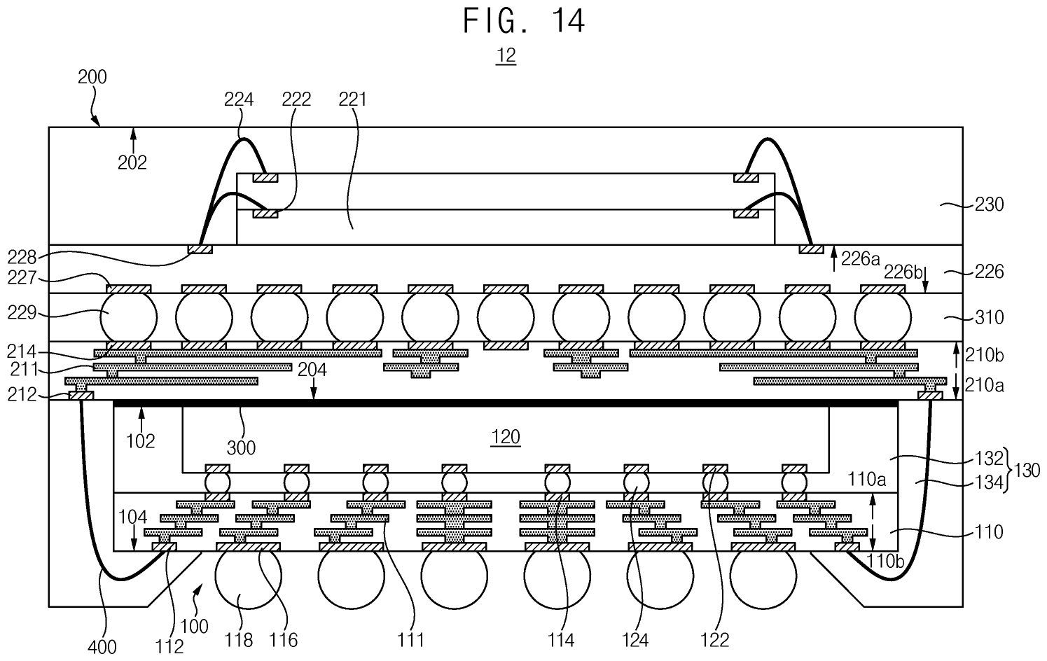

FIG. 14 is a cross-sectional view illustrating a semiconductor package including a semiconductor device mounted on an upper redistribution wiring layer by solder bumps in accordance with example embodiments. The semiconductor package may be substantially the same as or similar to the semiconductor package described with reference to FIG. 1 except for a configuration of the second semiconductor device. Thus, same or similar components are denoted by the same or similar reference numerals, and repeated descriptions of the same components will be omitted.

Referring to FIG. 14, the semiconductor package 12 may include the first sub-package 100 having the first redistribution wiring layer 110 and the first semiconductor device 120, the second sub-package 200 having the second redistribution wiring layer 210 and the second semiconductor device 220, the adhesive member 300 for bonding the first and second sub-packages 100, 200, and the first bonding wiring 400 electrically connecting the first and second redistribution wiring layers 110, 210 to each other.

In example embodiments, the second semiconductor device 220 may include a plurality of stacked semiconductor chips 221, the second chip pads 222 respectively provided on upper surfaces of the semiconductor chips 221, the second bonding wirings 224 respectively extending from the second chip pads 222, and a substrate 226 on which the semiconductor chips 221 are disposed and a plurality of second solder bumps 229 provided on a lower surface of the substrate 226. The second semiconductor device 220 may be disposed on the fourth surface 210b of the second redistribution wiring layer 210.

In example embodiments, the substrate 226 may be disposed on the second redistribution wiring layer 210 via second solder bumps 229. The substrate 226 may include fifth and sixth surfaces 226a, 226b opposite to each other. The substrate 226 may be provided, such that the sixth surface 226b faces the second redistribution wiring layer 210.

The substrate 226 may include a plurality of third redistribution wirings and third insulating layers. The substrate 226 may include a plurality of third connection pads 228 are configured to be exposed to an upper surface of the substrate 226, that is, the fifth surface 226a, and a plurality of bonding pads 227 configured to be exposed to a lower surface of the substrate 226, that is, the sixth surface 226b.

The third redistribution wiring may be provided in the third insulating layers. The third redistribution wirings may electrically connect the third connection pads 228 and the bonding pads 227 to each other. The third redistribution wiring may electrically connect the first and second semiconductor devices 120, 220. For example, the third redistribution wiring may include aluminum (Al), copper (Cu), tin (Sn), nickel (Ni), gold (Au), platinum (Pt), or an alloy thereof. The third redistribution wiring may be formed by a plating process, an electroless plating process, a vapor deposition process, or the like.

The third insulating layers may include sixth openings that expose the bonding pads 227 to the sixth surface 226b and seventh openings that expose the third connection pads 228 to the fifth surface 226a. For example, the third insulating layer may include a polymer, a dielectric layer, or the like. The third insulating layer may be formed by a vapor deposition process, a spin coating process, or the like.

The bonding pad 227 may be provided in the third insulating layer. The bonding pad 227 may contact the third redistribution wiring through the sixth opening. Accordingly, the plurality of bonding pads 227 may be configured to be exposed from the lower surface of the substrate 226, that is, the sixth surface 226b. The bonding pad 227 may be bonded to the second solder bump 229.

The third connection pad 228 may be provided in the third insulating layer. The third connection pad 228 may contact the third redistribution wiring through the seventh opening. Accordingly, the plurality of third connection pads 228 may be configured to be exposed from the upper surface of the substrate 226, that is, the fifth surface 226a. The third connection pads 228 may respectively contact the second bonding wirings 224 of the semiconductor chip 221.

The bonding pad 227, the third connection pad 228, and the third redistribution wiring may include the same conductive metal material. For example, the conductive metal material may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), or an alloy thereof.

Hereinafter, a method of manufacturing the semiconductor package in FIG. 14 will be described.

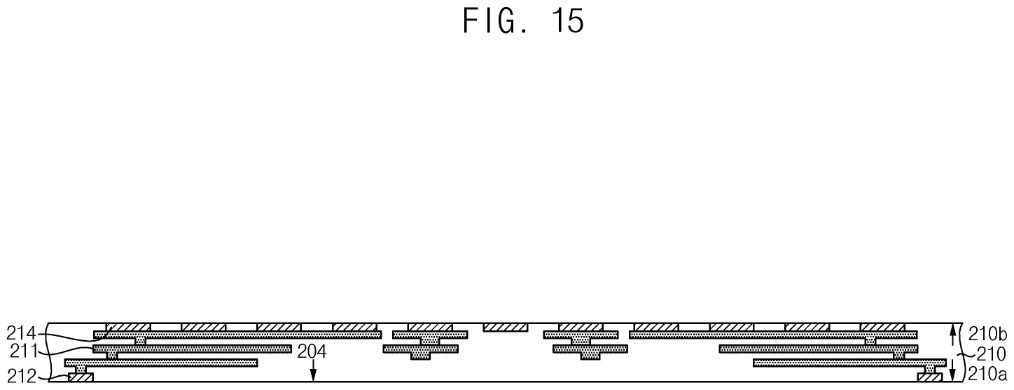

FIGS. 15 to 17 are cross-sectional views illustrating a method of manufacturing a semiconductor package in FIG. 14 in accordance with example embodiments.

Referring to FIG. 15, the second semiconductor wafer W2 including the second redistribution wiring layer 210 having the plurality of second redistribution connection pads 212 and the plurality of second connection pads 214 may be formed. The second redistribution wiring layer 210 may have the third surface 210a to which the second connection pads 214 are exposed and fourth surface 210b opposite to the third surface 210a.

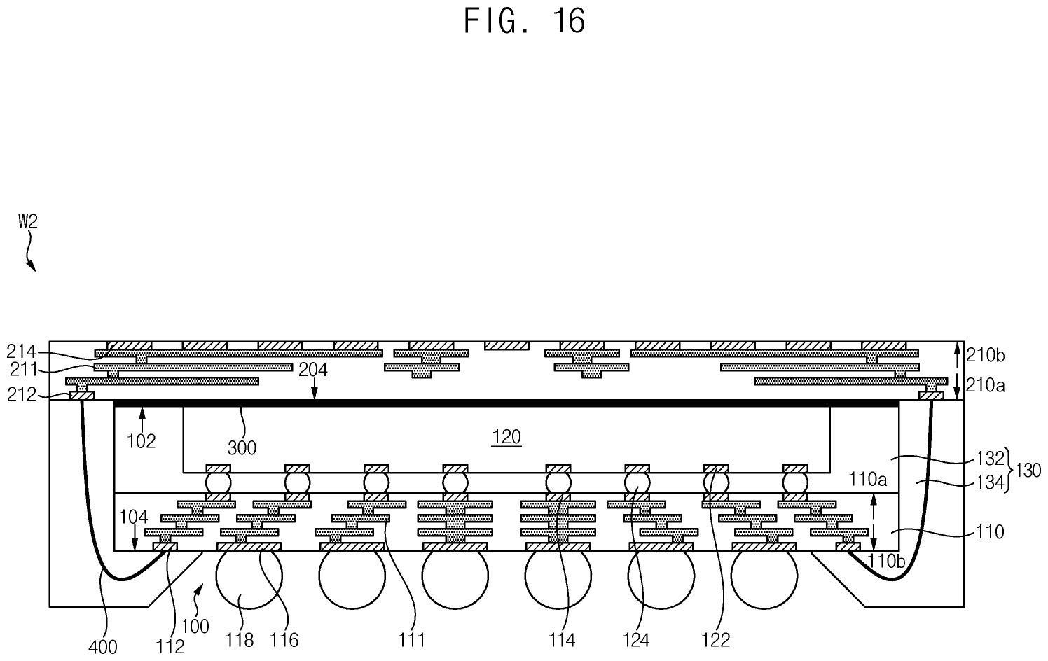

Referring to FIG. 16, the first sub-package 100 may be adhered to the second redistribution wiring layer 210 of the second semiconductor wafer W2 through the adhesive member 300. The first sub-package 100 may be adhered to the position corresponding to the second sub-package 200 of the second semiconductor wafer W2. The first sub-package 100 may be attached on the third surface 210a of the second redistribution wiring layer 210.

Then, first bonding wirings 400 connecting the second semiconductor wafer W2 and the first sub-package 100 may be formed. The first bonding wiring 400 may extend from the first redistribution connection pad 112 of the first sub-package 100 to the second redistribution connection pad 212 of the second semiconductor wafer W2.

Then, the sealing structure 134 on and covering at least a portion of the first sub-package 100, the first bonding wiring 400, and the third surface 210a of the second redistribution wiring layer 210 may be formed.

Then, external connection bumps 118 may be respectively formed on the external connection redistribution pads 116.

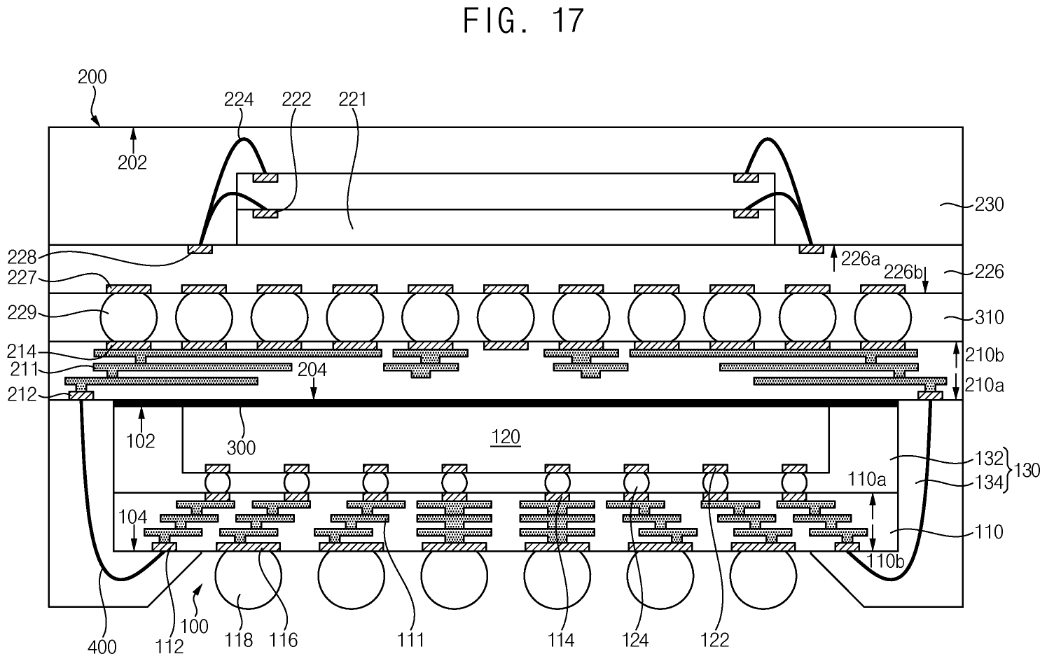

Referring to FIG. 17, the second semiconductor device 220 may be disposed on the fourth surface 210b of the second redistribution wiring layer 210. The second semiconductor device 220 may be the second sub-package 200.

The second semiconductor device 220 may be disposed on the second redistribution wiring layer 210 by a wire bonding method. In this case, the second semiconductor device 220 may be disposed on the second redistribution wiring layer 210, such that the active surface on which the second chip pads 222 are formed faces the opposite direction of the second redistribution wiring layer 210. The second chip pads 222 of the second semiconductor device 220 may be electrically connected to the second connection pads 214 of the second redistribution wiring layer 210 by the second bonding wirings 224 as conductive connection members.

The second semiconductor device 220 may be disposed on the second redistribution wiring layer 210 by a flip chip bonding method. The bonding pads 227 of the second semiconductor device 220 may be electrically connected to the second connection pads 214 of the second redistribution wiring layer 210 by the second solder bumps 229. For example, the second solder bumps 229 may include micro bumps (uBump).

The second semiconductor device 220 may be attached on the fourth surface 210b of the second redistribution wiring layer 210 by performing a thermal compression process at a predetermined temperature (e.g., about 400° C. or less). The second semiconductor device 220 and the second redistribution wiring layer 210 may be bonded to each other through the thermal compression process. That is, the second solder bumps 229 of the second semiconductor device 220 may be respectively bonded to the second connection pads 214 formed on the fourth surface 210b of the second redistribution wiring layer 210.

Then, an underfill adhesive 310 may be formed between the second semiconductor device 220 and the second semiconductor wafer W2. For example, the adhesive may include an epoxy material to reinforce a gap between the second semiconductor device 220 and the second semiconductor wafer W2.

Then, the second semiconductor wafer W2 may be cut along a scribe lane to form an individual semiconductor package 12. The second semiconductor wafer W2 may be cut by a dicing process. The semiconductor package 12 including the first sub-package 100 and the second sub-package 200 may be formed by cutting the second semiconductor wafer W2.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a first redistribution wiring layer;
a first semiconductor device on an upper surface of the first redistribution wiring layer;
a first sealing member on the first semiconductor device;
a second redistribution wiring layer on the first sealing member, such that a peripheral region of a lower surface of the second redistribution wiring layer is free of the first sealing member;
at least one second semiconductor device on an upper surface of the second redistribution wiring layer; and
a plurality of bonding wirings electrically connecting first redistribution connection pads on a lower surface of the first redistribution wiring layer and second redistribution connection pads on the peripheral region of the lower surface of the second redistribution wiring layer.

2. The semiconductor package of claim 1, wherein the first redistribution connection pads are in a peripheral region of the first redistribution wiring layer.

3. The semiconductor package of claim 1, further comprising:
a second sealing member on an outer region of the lower surface of the second redistribution wiring layer and on the plurality of bonding wires.

4. The semiconductor package of claim 1, further comprising:
a third sealing member on the upper surface of the second redistribution wiring layer and on the at least one second semiconductor device.

5. The semiconductor package of claim 1, wherein the first semiconductor device is connected to the first redistribution wiring layer via conductive bumps that are formed on first chip pads provided on an active surface of the first semiconductor device.

6. The semiconductor package of claim 1, further comprising:
external connection redistribution pads on first redistribution pads on the lower surface of the first redistribution wiring layer.

7. The semiconductor package of claim 6, wherein the external connection redistribution pads are on a central region of the first redistribution wiring layer.

8. The semiconductor package of claim 1, further comprising:
an adhesive member between the first sealing member and the second redistribution wiring layer.

9. The semiconductor package of claim 1, wherein the bonding wiring includes copper (Cu), aluminum (Al), tungsten (W), nickel (Ni), molybdenum (Mo), gold (Au), silver (Ag), chromium (Cr), tin (Sn) and/or titanium (Ti).

10. The semiconductor package of claim 1, wherein the second semiconductor device further includes:
a substrate having upper and lower surfaces opposite to each other;
a semiconductor chip on the upper surface of the substrate and electrically connected to the substrate through second bonding wires; and
a plurality of second solder bumps on the lower surface and joined to the second redistribution wiring layer.

11. A method of manufacturing a semiconductor package, comprising:
forming a first sub-package including a first semiconductor device on a first redistribution wiring layer and a first sealing member on the first semiconductor device, the first redistribution wiring layer having first redistribution connection pads on a lower surface of the first redistribution wiring layer;
forming a second sub-package including a second semiconductor device on a second redistribution wiring layer and a second sealing member on the second redistribution wiring layer, the second redistribution wiring layer having second redistribution connection pads on a lower surface of a peripheral region of the second redistribution wiring layer;
bonding the first sealing member to the second redistribution wiring layer to stack the second sub-package on the first sub-package; and
forming a plurality of bonding wirings electrically connecting the first and second redistribution connection pads to each other.

12. The method of claim 11, wherein forming the first sub-package includes: forming the first redistribution wiring layer, such that the first redistribution connection pads are in a peripheral region.

13. The method of claim 11, further comprising:
forming a third sealing member on an outer region of the lower surface of the second redistribution wiring layer and on the plurality of bonding wirings.

14. The method of claim 11, wherein forming the first sub-package further includes connecting the first semiconductor device to the first redistribution wiring layer via conductive bumps that are formed on first chip pads provided on an active surface of the first semiconductor device.

15. The method of claim 11, wherein forming the second sub-package further includes extending second conductive wirings from second chip pads provided on an active surface to respectively electrically connect the second semiconductor device to the second redistribution wiring layer.

16. The method of claim 11, wherein forming the first sub-package further includes forming the first redistribution wiring layer to expose a plurality of external connection redistribution pads from the lower surface of the first redistribution wiring layer;
the method further comprising:
forming a plurality of external connection bumps on the external connection redistribution pads, respectively.

17. The method of claim 16, wherein forming of the first redistribution wiring layer includes forming the external connection redistribution pads on a central region of the first redistribution wiring layer.

18. The method of claim 11, wherein the bonding wiring includes copper (Cu), aluminum (Al), tungsten (W), nickel (Ni), molybdenum (Mo), gold (Au), silver (Ag), chromium (Cr), tin (Sn) and/or titanium (Ti).

19. The method of claim 11, wherein bonding the first sealing member to the second redistribution wiring layer further includes bonding the first sealing member to the second redistribution wiring layer by using an adhesive member therebetween.

20. A semiconductor package, comprising:
a first sub-package having a first upper surface and a first lower surface opposite to each other, the first sub-package having a first redistribution wiring layer having a plurality of first redistribution connection pads exposed from the first lower surface, a first semiconductor device on the first redistribution wiring layer and a first sealing member on the first semiconductor device;
a second sub-package having a second upper surface and a second lower surface opposite to each other, the second sub-package having a second redistribution wiring layer having a plurality of second redistribution connection pads and external connection redistribution pads exposed from the second lower surface, a second semiconductor device mounted on the second redistribution wiring layer, and a second sealing member on the second semiconductor device;
an adhesive member between the first upper surface of the first sub-package and the second lower surface of the second sub-package to bond the first and second sub-packages;
a plurality of first bonding wirings electrically connecting the first and second redistribution connection pads to each other; and
external connection bumps on the external connection redistribution pads, respectively.
